(19) United States
(12) Patent Application Publication
(10) Pub. No.: US 2018/0211997 A1
(43) Pub. Date: Jul. 26, 2018

(54) STRUCTURE OF RANDOM ACCESS MEMORY

(71) Applicant: Industrial Technology Research Institute, Hsinchu (TW)

(72) Inventors: Yu-De Lin, Taoyuan City (TW); Heng-Yuan Lee, Hsinchu County (TW)

(73) Assignee: Industrial Technology Research Institute, Hsinchu (TW)

(21) Appl. No.: 15/453,914

(22) Filed: Mar. 9, 2017

(30) Foreign Application Priority Data
Jan. 26, 2017 (TW) 106103091

(51) Int. Cl. H01L 27/24; H01L 45/00

(52) U.S. Cl. CPC H01L 27/2427; H01L 27/2463; H01L 45/1233; H01L 45/06; H01L 45/144; H01L 45/1253

(57) ABSTRACT

A structure of random access memory includes a memory cell and a selector. The memory cell has two different conductive states according to a bias applied on the memory cell. The selector is electrically connected to the memory cell in series. An operation voltage is applied between two end terminals of the memory cell and the selector connected in series. A structure of the selector formed from multiple capacitors coupled in series, includes a plurality of dielectric layers corresponding to the capacitors; and a metal conductive layer, disposed between the dielectric layers. A material of the metal conductive layer is to resist a material inter-diffusion between adjacent two of the dielectric layers in different materials.

### CROSS-REFERENCE TO RELATED APPLICATION

This application claims the priority benefit of Taiwan application serial no. 106103091, filed on Jan. 26, 2017. The entirety of the above-mentioned patent application is hereby incorporated by reference herein and made a part of this specification.

### TECHNICAL FIELD

The present disclosure generally relates to random access memory, relates to a random access memory having a memory cell with two conductive states and a selector.

### BACKGROUND

The non-volatile memory in the digital electronic products is almost the necessary part, indispensably. The digital electronic products as the example are computer system, mobile phone, camera, video recorder, and so on, which are indispensable products in the current daily life. Therefore, the non-volatile memory is widely required.

Further due to the current development on multimedia, it accordingly needs a large amount of data to be stored and therefore the design for the non-volatile memory is continuously under development. The newly developed technology, it generally includes magnetoresistive random access memory (MRAM), phase change random access memory (PCRAM), and resistive random access memory (RRAM).

As to the PCRAM and the RRAM, their characteristics are using the operation voltages as applied to change the conductive state of the memory material, so to store the bit data. The conductive state is changed in accordance with the resistance level of the RAM. The memory material of PCRAM is using the crystal state to change the resistance level. The memory material of RRAM by itself is a resistor but the resistance level is not linearly changing with the applied voltage, of which two resistance states exits depending on the different applied voltage. It thereby can be used to storing bit data.

However, when the memory cell density of the memory array increases, the selected memory cell during operation would be also affected by the non-selected memory cells. For example, during the reading operation, a leakage current for the non-selected memory cells would occur, affecting the reading precision. In this situation, the memory cell is also implemented with a diode or a selector, to exclude the effect from the non-selected memory cells.

To the selector, it also has non-linear two resistance states depending on the applied voltage. The use with selection can surely turn off the non-selected memory cells.

However, the performance of the selector may be instable. For example, due to the high temperature annealing process in fabrication process would degrade the selector, in which the characteristics of two non-linear resistance states cannot be effectively maintained. The design for the selector is still under developing.

### SUMMARY

In an exemplary embodiment of the disclosure, a structure of random access memory comprises a memory cell and a selector. The memory cell has two different conductive states according to a bias applied on the memory cell. The selector is electrically connected to the memory cell in series, wherein an operation voltage is applied between two end terminals of the memory cell and the selector connected in series. A structure of the selector is formed from a plurality of capacitors coupled in series. The selector comprises: a plurality of dielectric layers, corresponding to the capacitors. A metal conductive layer is disposed between the dielectric layers, a material of the metal conductive layer being to resist a material inter-diffusion between adjacent two of the dielectric layers in different materials.

In an exemplary another embodiment of the disclosure, a structure of random access memory comprises a memory cell and a selector. The memory cell has two different conductive states according to a bias applied on the memory cell. The selector is electrically connected to the memory cell in series. An operation voltage is applied between two end terminals of the memory cell and the selector connected in series. The selector comprises: a plurality of ovonic threshold switch (OTS) material layers. A metal conductive layer, disposed between the OTS layers, a material of the metal conductive layer being to resist a material inter-diffusion between adjacent two of the OTS material layers in different materials.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a drawing, schematically illustrating a memory structure, according to an exemplary embodiment of the disclosure.

FIG. 2 is a drawing, schematically illustrating the characteristics of resistive memory, according to an exemplary embodiment of the disclosure.

FIG. 3 is a drawing, schematically illustrating the cross-sectional stack structure of the resistive memory, according to an exemplary embodiment of the disclosure.

FIG. 4 is a drawing, schematically illustrating the cross-sectional stack structure of the resistive memory, according to an exemplary embodiment of the disclosure.

FIG. 5 is a drawing, schematically illustrating the cross-sectional structure of the selector, according to an exemplary embodiment of the disclosure.

### DESCRIPTION OF THE EMBODIMENTS

To increase the storage capacity of memory, the structure of 3-dimensional vertical memory has been proposed. Some exemplary embodiments are provided for disclosure, but the disclosure is not just limited to the exemplary embodiments.

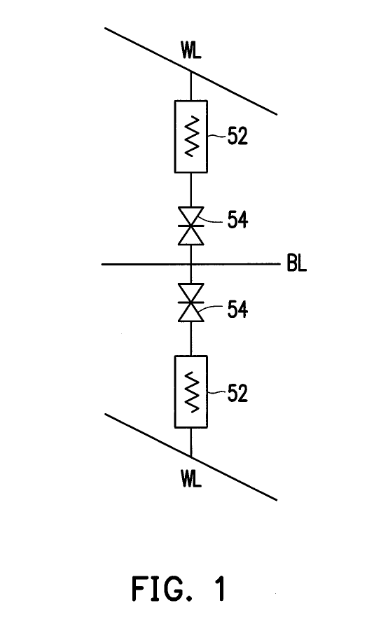

Taking the resistive memory as an example, multiple memory layers can be stacked up along a direction perpendicular to a substrate. FIG. 1 is a drawing, schematically illustrating a memory structure, according to an exemplary embodiment of the disclosure. Referring to FIG. 1, a memory unit having a memory cell 52 implemented with a selector 54 as an exemplary embodiment is taken to describe the structure of vertical memory. Here, the memory cell 52 as an example is a resistive, memory but can also be a phase change memory. Bu using the control of applying voltage, the resistance level of the memory cell 52 can be set to a high resistance state or low resistance state. A memory unit is controlled by word line and bit line, which are crossing to each other, and a multiple memory units can be fabricated along the vertical direction. Further, based on the 2-dimensional layout, the memory units in the same layer are a 2-dimensional array. After extending along the vertical direction, the 3-dimensional structure of vertical memory is formed.

As to the storage mechanism of the memory cell 52, it can be generally categorized into unipolar structure or bipolar structure. The bipolar property refers that the applied voltages have positive and negative polarities, so to set the memory cell 52 to be high resistance state or low resistance state. The unipolar refers that the applied voltages are all in positive polarity, in which the resistance state is changed when the voltage is crossing over a threshold. Either in bipolar structure or unipolar structure, the memory cell 52 can be set or written to a high resistance state or low resistance state by properly applying the voltages.

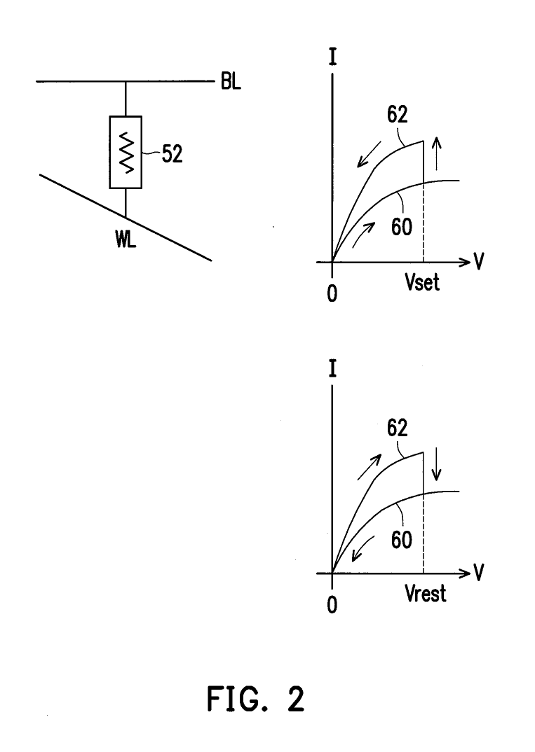

FIG. 2 is a drawing, schematically illustrating the characteristics of resistive memory, according to an exemplary embodiment of the disclosure. Referring to FIG. 2, taking the unipolar operation mechanism as an example, it uses the corresponding word line and bit line to apply voltage onto the memory cell 52. As observing on the V-I curve as applied, the memory cell 52 has high resistance state 60 and low resistance state 62. Assuming that the memory cell 52 is at the high resistance state 60, the applied voltage is varying along the curve of high resistance state 60 and reaches to the setting threshold voltage Vset, it would transit to the low resistance state 62. The response for the current (I) is rising up by a step. At this moment, if the applied voltage (V) changes back to 0V, the memory cell 52 along the V-I curve at the low resistance state 62 still remains at the low resistance state 62. Next, if the memory cell 52 is again applied the voltage (V), it will vary along the cure of low resistance state 62. When another reset threshold voltage Vrest is reached, the memory cell 52 then changes to the high resistance state 60.

The memory cell 52 has the function to store one bit by setting to the high resistance state 60 or low resistance state 62. If the memory cell 52 is a phase change memory, it can use the operation voltage to change the crystal phase of the memory material, so to achieve the setting to high resistance state and low resistance state. The storage mechanism of the memory cell 52 can refer to the ordinary skill in the art, without further description in detail. However, if the memory unit is just formed by one memory cell 52, during operation, it then easily causes current leakage to the memory cells not selected. Therefore, as shown in FIG. 1, the selector 54 is usually used accordingly.

The effect of selector 54 is like to the diode effect, which has two states of conductive state and non-conductive state. Whereby during operation, the selectors of the memory cells not selected can be turned off by applying a proper voltage, in which the selector 54 is at the non-conductive state. This can assure that the memory cells not selected have no leakage current.

In considering the fabrication cost, usually, the selector 54 is taken to replace the diode. That is because the selector 54 can be fabricated by proper dielectric materials or OTS material. However, the performance of the selector 54 may be degraded by high-temperature annealing process during the fabricating processes of the vertical stacked memory and cannot effectively maintain the two states of conductive state and non-conductive state. The disclosure proposes the selector structure, which can effectively reducing the degrading phenomenon for the selector 54.

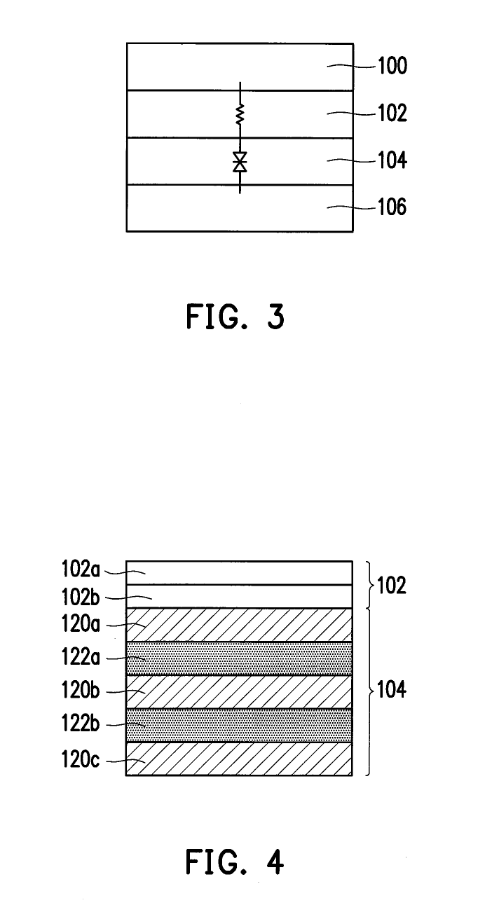

FIG. 3 is a drawing, schematically illustrating the cross-sectional stack structure of the resistive memory, according to an exemplary embodiment of the disclosure. Referring to FIG. 3, as to the stacked structure of memory, a memory cell 102 and a selector 104 are formed between a first electrode layer 100 and a second electrode layer 106. The first electrode layer 100 and the second electrode layer 106 are respectively receiving the voltages of word line and bit line, so to apply voltage to the memory cell 102 and the selector 104. The memory cell 102 in the exemplary embodiment includes a representative layer having the memory layer. The selector 104 is also representing a stacked layer from multiple layers of dielectric material or OTS material.

FIG. 4 is a drawing, schematically illustrating the cross-sectional stack structure of the resistive memory, according to an exemplary embodiment of the disclosure. Referring to FIG. 3 and FIG. 4, the structure of stacked layers is described in better detail. The memory cell 102 includes a memory material layer 102b having two different conductive states, as a resistive memory material or phase change memory material. In addition, it also has the connection layer 102a to electrically connect to the first electrode layer 100. Here, the connection layer 102a is not absolutely needed but can be added if the design for the actual connection structure needs it.

The selector 104 and the memory cell 102 are electrically connected in series, such the connection through the metal conductive layer 120a. The operation voltage can be applied through the first electrode layer 100 and the second electrode layer 106 between two end terminals of the memory cell 102 and the selector 104. The structure of the selector 104 in an exemplary embodiment can be multiple capacitors coupled in series, which include multiple dielectric layers 122a, 122b corresponding to the capacitors. In the exemplary embodiment, the number of the dielectric layers 122a, 122b is two as the example. The metal conductive layer 120b is between the two dielectric layers 122a, 122b. Material of the metal conductive layer 120b is to resist a material inter-diffusion between adjacent two of the dielectric layers 122a, 122b in different materials. The reasons to cause the material inter-diffusion can be thermal effect but also the factors of optical, plasma, . . . , and so on. The suitable material for the selector 104 is to be described later. Here, the metal conductive layer 120c as the bottom layer is also not the absolutely required element, which is used to easily electrically connect to the second electrode layer 106 and the apply voltage to the memory. In an exemplary embodiment, if the metal conductive layer 120c is neglected, then the dielectric layer 122b at the bottom is connected to the second electrode layer 106.

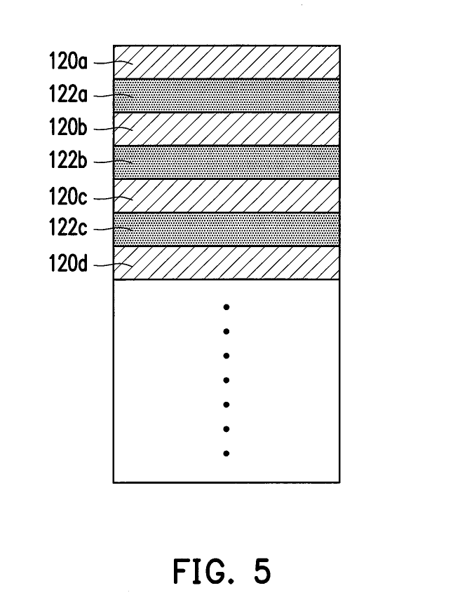

FIG. 5 is a drawing, schematically illustrating the cross-sectional structure of the selector, according to an exemplary embodiment of the disclosure. Referring to FIG. 5, it further describes the modification in structure for the selector 104. The number of dielectric layers 122a, 122b, 122c of the selector 104 can be three or more but the materials for the adjacent two dielectric layers are different, so the metal conductive layers 120a, 120c between adjacent two dielectric layers can resist the material inter-diffusion, which causes degrading performance for the selector. Here, the metal conductive layer 120c is the middle layer in the stack not the metal conductive later at the bottom. However, likewise, if the bottom layer is the metal conductive layer, it can be electrically connected to the electrode layer.

The suitable materials for the selector are described. The selector 104 can be categorized into three structures. As to the material for the dielectric layer, it can be transition metal oxide or metal sulphide. In addition, the dielectric layer can be replaced by OTS layer. The metal conductive layer can take oxidation-resistance metal, such as nitride metal, like Pt, Au et al. However, the disclosure is not limited these.

Taking the oxide as an example for the suitable material of the dielectric layer, it can be TiO₂, TaOₓ, or HfOₓ, for example. The metal conductive layer can be nitride metal, such as TiN, Pt, Au, or oxidation-resistance metal. Further, materials of the OTS layer can be metal semiconductor, SiTe, GeTe, ZnTe, GeSe et al. The suitable materials are listed in Table 1 but not limited thereto.

TABLE 1

| | |
|---|---|
| Metal | TaOₓ, TiOₓ, HfOₓ, AlOₓ, transition metal oxide (NiO [symbol] |
| conductive | MoOₓ [symbol] VOx [symbol] NbOₓ) |
| Metal | transition metal sulpgide (ZnS [symbol] AgS [symbol] CuS) |
| sulphide | |
| OTS | SiTe [symbol] GeTe [symbol] ZnTe [symbol] GeSe |

In this manner, if the dielectric layer of the selector is replaced by OTS layer, the selector is not the structure of multiple capacitors coupled in series. Therefore, in another exemplary embodiment, the invention provides a structure of random access memory comprises a memory cell and a selector. The memory cell has two different conductive states according to a bias applied on the memory cell. The selector is electrically connected to the memory cell in series. An operation voltage is applied between two end terminals of the memory cell and the selector connected in series. The selector comprises: a plurality of OTS material layers. A metal conductive layer, disposed between the OTS layers, a material of the metal conductive layer being to resist a material inter-diffusion between adjacent two of the dielectric layers in different materials.

As to the foregoing descriptions, In an exemplary embodiment of the disclosure, as to the structure of random access memory, the selector has a first state and a second state according to a bias applied on the selector, wherein the first state substantially is a conducting state and the second state substantially is a non-conducting state.

In an exemplary embodiment of the disclosure, as to the structure of random access memory, the memory cell is a phase change random access memory (PCRAM) or a resistive random access memory (RRAM).

In an exemplary embodiment of the disclosure, as to the structure of random access memory, a material of the dielectric layers is transition metal oxide or metal sulphide.

In an exemplary embodiment of the disclosure, as to the structure of random access memory, the metal conductive layer is nitride metal.

In an exemplary embodiment of the disclosure, as to the structure of random access memory, the metal conductive layer is nitride metal, Pt, Au, or oxidation-resistance metal.

As to the foregoing descriptions, the disclosure proposes the selector has a structure of multiple layers of dielectric or OTS. The selector can stably keep two non-linear resistance states.

The disclosure provides the selector structure, which is formed by multiple dielectric layers or OTS layers. In addition, the metal conductive layer is added between adjacent two dielectric layers or OTS layers, to avoid the material inter-diffusion between adjacent two dielectric layers or OTS layers, which would cause degrading performance for the selector. As a result, the material inter-diffusion between adjacent two dielectric layers or OTS layers can be effectively reduced.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

1. A structure of random access memory, comprising:
a memory cell, having two different conductive states according to a bias applied on the memory cell; and
a selector, electrically connected to the memory cell in series, wherein an operation voltage is applied between two end terminals of the memory cell and the selector connected in series, wherein a structure of the selector is formed from a plurality of capacitors coupled in series, the selector comprises:
a plurality of dielectric layers, corresponding to the capacitors; and
a metal conductive layer, disposed between the dielectric layers, a material of the metal conductive layer being to resist a material inter-diffusion between adjacent two of the dielectric layers in different materials.

2. The structure of random access memory as recited in claim 1, wherein the selector has a first state and a second state according to a bias applied on the selector, wherein the first state is a conducting state and the second state is a non-conducting state.

3. The structure of random access memory as recited in claim 1, wherein the memory cell is a phase change random access memory (PCRAM) or a resistive random access memory (RRAM).

4. The structure of random access memory as recited in claim 1, wherein a material of the dielectric layers is transition metal oxide or metal sulphide.

5. The structure of random access memory as recited in claim 1, wherein the metal conductive layer is a nitride metal.

6. The structure of random access memory as recited in claim 1, wherein the metal conductive layer is nitride metal, Pt, Au, or oxidation-resistance metal.

7. A structure of random access memory, comprising:
a memory cell, having two different conductive states according to a bias applied on the memory cell; and
a selector, electrically connected to the memory cell in series, wherein an operation voltage is applied between two end terminals of the memory cell and the selector connected in series, wherein the selector comprises:
a plurality of ovonic threshold switch (OTS) material layers; and
a metal conductive layer, disposed between the OTS layers, a material of the metal conductive layer being to resist a material inter-diffusion between adjacent two of the OTS material layers in different materials.

8. The structure of random access memory as recited in claim 7, wherein the selector has a first state and a second state according to a bias applied on the selector, wherein the first state s is a conducting state and the second state is a non-conducting state.

9. The structure of random access memory as recited in claim 7, wherein the memory cell is a phase change random access memory (PCRAM) or a resistive random access memory (RRAM).

10. The structure of random access memory as recited in claim 7, wherein a material of the OTS layers is a metal semiconductor.

11. The structure of random access memory as recited in claim 10, wherein the material of the metal semiconductor is SiTe, GeTe, GeSe, or ZnTe.

12. The structure of random access memory as recited in claim 7, wherein the metal conductive layer is a nitride metal.

13. The structure of random access memory as recited in claim 7, wherein the metal conductive layer is nitride metal, Pt, Au, or oxidation-resistance metal.

14. A structure of random access memory, comprising:
a memory cell, having two different conductive states according to a bias applied on the memory cell; and
a selector, electrically connected to the memory cell in series, wherein an operation voltage is applied between two end terminals of the memory cell and the selector connected in series, wherein the selector comprises:
a plurality of metal conductive layers; and
a plurality of selector material layers, each of the selector material layers being sandwiched between adjacent two of the metal conductive layers, wherein the selector material layers have an electrical property to form the selector, and a material of the metal conductive layer is to resist a material inter-diffusion between adjacent two of the selector material layers.
